(19) United States
(12) Patent Application Publication
(10) Pub. No.: US 2026/0182141 A1
(43) Pub. Date: Jun. 25, 2026

(54) Light Emitting Device and Light Emitting Display Device Including the Same

(71) Applicant: LG Display Co., Ltd., Seoul (KR)

(72) Inventors: Yu Jeong Lee, Paju-si (KR); Eun Jung Park, Paju-si (KR); Seung Hyun Kim, Paju-si (KR); Chun Ki Kim, Paju-si (KR)

(21) Appl. No.: 19/397,420

(22) Filed: Nov. 21, 2025

(30) Foreign Application Priority Data
Dec. 24, 2024 (KR) 10-2024-0195855

(51) Int. Cl. H10K 50/19; H10K 50/13; H10K 101/00; H10K 101/30

(52) U.S. Cl. CPC H10K 50/19; H10K 50/13; H10K 2101/30; H10K 2101/90

(57) ABSTRACT

Disclosed is a light emitting device preventing a defect in which light with a specific color is observed when switching from a black state to a low-grayscale state. The light emitting device includes a first electrode and a second electrode facing each other, and a green light emitting stack including a hole transport layer, a green light emitting layer, and an electron transport layer disposed between the first electrode and the second electrode, wherein the green light emitting layer includes a hole transport host, an electron transport host, and a green dopant, a HOMO energy level of the green dopant is lower than a HOMO energy level of the hole transport host and is higher than a HOMO energy level of the electron transport host, and a HOMO energy level of the electron transport host is higher than the HOMO energy level of the electron transport layer.

### CROSS-REFERENCE TO RELATED APPLICATIONS

This application claims the benefit of Republic of Korea Patent Application No. 10-2024-0195855, filed on Dec. 24, 2024, which is hereby incorporated by reference as if fully set forth herein.

### BACKGROUND

### Field

The present disclosure relates to a light emitting device that is imparted with improved image quality and efficiency, and a light emitting display device including the same.

### Discussion of the Related Art

With the advent of the information society, displays for visually expressing electrical information signals have rapidly developed. In response to this, a variety of display devices with excellent performance such as slimness, low weight, and low power consumption are being developed.

Thereamong, a light emitting display device that does not require a separate light source to realize compactness and clear color and has a light emitting device in a display panel has been considered as a competitive application.

The light emitting device may include an anode and a cathode facing each other as electrodes, a light emitting layer between the anode and the cathode, and a common layer for transferring holes and electrons to the light emitting layer.

Meanwhile, the light emitting device may include various functional layers for various functions, for example, in the common layer. The functional layers include a hole transport layer for transferring holes to the light emitting layer and the electron transport layer for transferring electrons to the light emitting layer.

### SUMMARY

Accordingly, the present disclosure is directed to a light emitting device and a light emitting display device including the same that substantially obviate one or more problems due to limitations and disadvantages of the related art.

The light emitting device may include light emitting layers that emit light of different colors to express various colors.

Meanwhile, recently, light emitting display devices including different light emitting layers have been problematic in that flashing occurs when a specific color is prominent when switched from a black state to a low-grayscale state.

It is one object of the present disclosure to provide a light emitting device that is capable of improving poor image quality in which a specific color is prominent when switched from an off state (black state) to a low-grayscale state in a structure including light emitting layers that emit light of different colors.

It is another object of the present disclosure to provide a light emitting display device that is capable of improving the efficiency of a green light emitting stack that plays a pivotal role in color expression.

Additional advantages, objects, and features of the invention will be set forth in part in the description which follows and in part will become apparent to those having ordinary skill in the art upon examination of the following or may be learned from practice of the disclosure. The objectives and other advantages of the invention may be realized and attained by the structure particularly pointed out in the written description and claims hereof as well as the appended drawings.

To achieve these objects and other advantages and in accordance with the purpose of the disclosure, as embodied and broadly described herein, a light emitting device includes a first electrode and a second electrode facing each other, and a green light emitting stack including a hole transport layer, a green light emitting layer, and an electron transport layer disposed between the first electrode and the second electrode, wherein the green light emitting layer includes a hole transport host, an electron transport host, and a green dopant, a HOMO energy level of the green dopant is lower than a HOMO energy level of the hole transport host and is higher than a HOMO energy level of the electron transport host, and a HOMO energy level of the electron transport host is higher than the HOMO energy level of the electron transport layer.

In accordance with another aspect of the present disclosure, a light emitting display device includes a substrate including a plurality of subpixels, a pixel circuit provided in each of the plurality of subpixels, the pixel circuit comprising at least one transistor, and the light emitting device connected to the pixel circuit in at least one of the subpixels.

It is to be understood that both the foregoing general description and the following detailed description of the present disclosure are exemplary and explanatory and are intended to provide further explanation of the invention as claimed.

### BRIEF DESCRIPTION OF THE DRAWINGS

The accompanying drawings, which are included to provide a further understanding of the invention and are incorporated in and constitute a part of this application, illustrate embodiment(s) of the invention and together with the description serve to explain the principle of the invention. In the drawings:

FIG. 1 is a cross-sectional view illustrating a light emitting device according to an embodiment of the present disclosure;

FIG. 2 is an energy band diagram of a green light emitting stack;

FIGS. 3A and 3B illustrate hole transport of a first green dopant having a higher HOMO energy level than a HOMO energy level of a hole transport host and a green dopant having a lower HOMO energy level than a HOMO energy level of the hole transport host;

FIG. 4A is a graph showing the JV characteristics of a HOD device when the hole transport host GHH, the first green dopant GD1, and the green dopant GD of the embodiment of the present disclosure are included in the active layer;

FIG. 4B is a graph showing the JV characteristics of the EOD device when the active layer includes the electron transport host GEH, the first green dopant GD1, and the green dopant GD of the embodiment of the present disclosure;

FIGS. 5A to 5D are energy band diagrams of Experimental Examples 1 to 4 in which the materials for the green dopant and the electron transport host in the green light emitting layer are different in the green light emitting stack;

FIG. 6 shows movement of carriers to the first green dopant in the green light emitting layer including the hole transport host, the first electron transport host, and the first green dopant of the light emitting device according to Experimental Example 1;

FIG. 7 shows movement of carriers to the green dopant in the green light emitting layer including the hole transport host, the electron transport host, and the green dopant of the light emitting device according to the embodiment of the present disclosure;

FIG. 8 is a graph showing the CV characteristics of the green light emitting stacks of Experimental Examples 1 to 4;

FIGS. 9A to 9C are graphs showing the luminance when switched from a black state to a low-grayscale state of Experimental Examples 2 to 4 compared to Experimental Example 1;

FIG. 10 is a schematic diagram illustrating the electron transport host of the embodiment of the present disclosure;

FIG. 11 is a cross-sectional view illustrating a light emitting device according to another embodiment of the present disclosure;

FIG. 12 is a cross-sectional view illustrating a light emitting display device according to one embodiment of the present disclosure; and

FIG. 13 is a cross-sectional view illustrating a light emitting display device according to another embodiment of the present disclosure.

### DETAILED DESCRIPTION

Advantages and features of the present disclosure, and a method of achieving the advantages and features will become apparent with reference to the example embodiments described herein in detail together with the accompanying drawings. The present disclosure should not be construed as limited to the example embodiments as disclosed below, and can be embodied in various different forms. Thus, these example embodiments are set forth only to make the present disclosure sufficiently complete, and to assist those skilled in the art to fully understand the scope of the present disclosure. The protected scope of the present disclosure is defined by the claims and their equivalents.

In the following description of the present disclosure, where the detailed description of the relevant known steps, elements, functions, technologies, and configurations can unnecessarily obscure an important point of the present disclosure, a detailed description of such steps, elements, functions, technologies, and configurations maybe omitted. In addition, the names of elements used in the following description are selected in consideration of clarity of description of the specification, and can differ from the names of elements of actual products. Furthermore, in the following detailed description of the present disclosure, numerous specific details are set forth in order to provide a sufficiently thorough understanding of the present disclosure. However, it will be understood that the present disclosure can be practiced without these specific details. In other instances, known methods, procedures, components, and circuits have not been described in detail so as not to unnecessarily obscure aspects of the present disclosure.

The shapes, sizes, ratios, angles, numbers, and the like, which are illustrated in the drawings to describe various example embodiments of the present disclosure are merely given by way of example. The disclosure is not limited to the illustrations in the drawings.

In the present specification, where terms such as “including,” “having,” “comprising,” and the like are used, one or more components can be added, unless the term, such as “only,” is used. As used herein, the term “and/or” includes a single associated listed item and any and all of the combinations of two or more of the associated listed items.

An expression such as “at least one of” when preceding a list of elements can modify the entire list of elements and may not modify the individual elements of the list. The term “at least one” should be understood as including any and all combinations of one or more of the associated listed items. For example, the meaning of “at least one of a first element, a second element, and a third element” encompasses the combination of all three listed elements, combinations of any two of the three elements, as well as each individual element, the first element, the second element, and the third element.

The terminology used herein is to describe particular aspects and is not intended to limit the present disclosure. As used herein, the terms “a” and “an” used to describe an element in the singular form is intended to include a plurality of elements. An element described in the singular form is intended to include a plurality of elements, and vice versa, unless the context clearly indicates otherwise.

In construing a component or numerical value, the component or the numerical value is to be construed as including an error or tolerance range even where no explicit description of such an error or tolerance range is provided.

In describing the various example embodiments of the present disclosure, where the positional relationship between two elements is described using terms, such as “on”, “above”, “under” and “next to”, at least one intervening element can be present between the two elements, unless “immediate(ly)” or “direct(ly)” or “close(ly) is used. It will be understood that when an element or layer is referred to as being “connected to”, or “coupled to” another element or layer, it can be directly connected to or coupled to the other element or layer, or one or more intervening elements or layers can be present.

In describing the various example embodiments of the present disclosure, when terms such as “after,” “subsequently,” “next,” and “before,” are used to describe the temporal relationship between two events, another event can occur therebetween, unless a more limiting term, such as “just,” “immediate(ly),” or “directly” is used.

In describing the various example embodiments of the present disclosure, terms such as “first” and “second” can be used to describe a variety of components. These terms aim to distinguish the same or similar components from one another and do not limit the components. Accordingly, throughout the specification, a “first” component can be the same as a “second” component within the technical concept of the present disclosure, unless specifically mentioned otherwise.

Features of various embodiments of the present disclosure can be partially or overall coupled to or combined with each other, and can be variously inter-operated with each other and driven technically as those skilled in the art can sufficiently understand. The embodiments of the present disclosure can be carried out independently from each other, or can be carried out together in a co-dependent relationship.

As used herein, the term “LUMO (lowest unoccupied molecular orbital) energy level” and “HOMO (highest occupied molecular orbital) energy level” of a layer refer to the LUMO energy level and HOMO energy level of a material that occupies most of a weight ratio of the layer, for example, a host material, unless the context clearly mentions that the LUMO energy level and the HOMO energy level mean the LUMO energy level and HOMO energy level of a dopant material with which the layer is doped, respectively.

Here, the HOMO energy level is obtained by measuring the voltage corresponding to a first peak at which electrons are discharged from a target material through cyclic voltammetry (CV) while comparing with a reference material whose HOMO energy level is known. For example, the HOMO energy level of a substance may be measured based on a substance whose oxidation potential and reduction potential are known.

As used herein, the term “doped” layer refers to a layer including a first material and a second material (for example, n-type and p-type materials, or organic and inorganic substances) having physical properties different from the first material. Apart from the differences in properties, the first and second materials can also differ in terms of their amounts in the doped layer. For example, the host material can be a major component while the dopant material can be a minor component. The first material accounts for most of the weight of the doped layer. The second material can be added in an amount less than 30% by weight, based on a total weight of the first material in the doped layer. A “doped” layer can be a layer that is used to distinguish a host material from a dopant material of a certain layer, in consideration of the weight ratio. For example, if all of the materials constituting a certain layer are organic materials, at least one of the materials constituting the layer is n-type and the other is p-type, when the n-type material is present in an amount of less than 30 wt %, or when the p-type material is present in an amount of less than 30 wt %, the layer is considered to be a “doped” layer.

Further, the term “undoped” refers to layers that are not “doped”. For example, a layer can be an “undoped” layer when the layer contains a single material or a mixture including materials having the same properties as each other. For example, if at least one of the materials constituting a certain layer is p-type and none of the materials constituting the layer are n-type, the layer is considered to be an “undoped” layer. For example, if at least one of the materials constituting a layer is an organic material and none of the materials constituting the layer are inorganic materials, the layer is considered to be an “undoped” layer.

In this present disclosure, an electroluminescence (EL) spectrum can be calculated by multiplying (a) a photoluminescence (PL) spectrum, which applies the inherent characteristics of an emissive material such as a dopant material or a host material included in an organic emission layer, by (b) an out-coupling or emittance spectrum curve, which is determined by the structure and optical characteristics of an organic light-emitting element including the thicknesses of organic layers such as, for example, an electron transport layer.

Hereinafter, example embodiments of the present disclosure will be described in detail with reference to the accompanying drawings. In adding reference numerals to elements of each of the drawings, although the same elements are illustrated in other drawings, like reference numerals can refer to like elements.

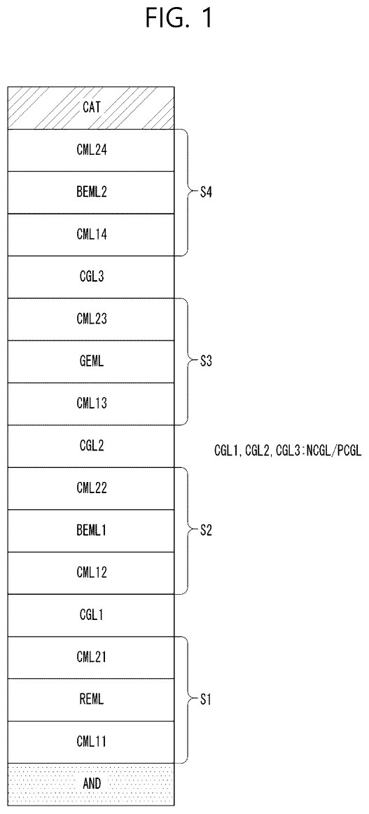

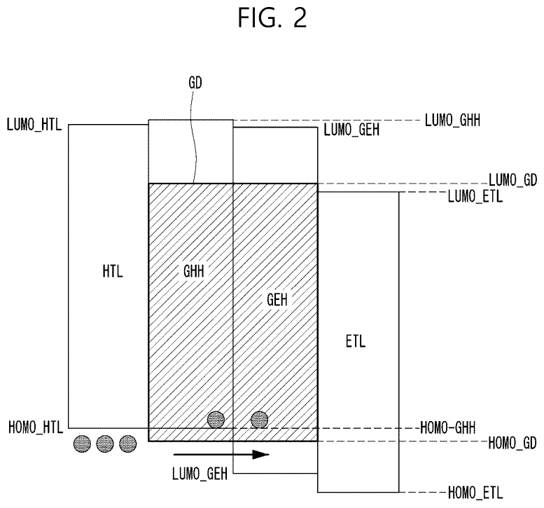

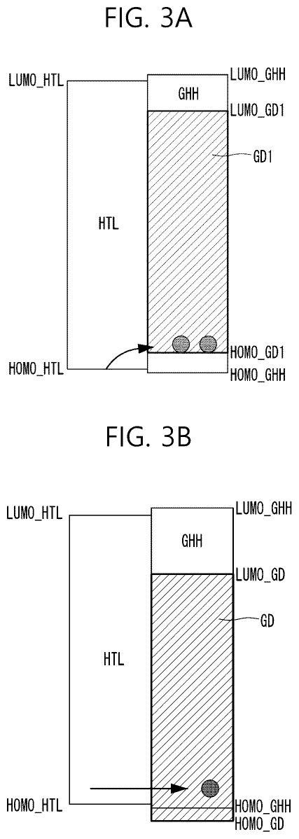

FIG. 1 is a cross-sectional view illustrating a light emitting device according to an embodiment of the present disclosure. FIG. 2 is an energy band diagram of a green light emitting stack according to an embodiment of the present disclosure. FIGS. 3A and 3B illustrate hole transport of a first green dopant having a higher HOMO energy level than a HOMO energy level of a hole transport host and a green dopant having a lower HOMO energy level than a HOMO energy level of the hole transport host.

A light emitting device according to an embodiment of the present disclosure is provided in at least one subpixel of a light emitting display device.

As shown in FIG. 1, the light emitting device according to an embodiment of the present disclosure includes a first electrode AND and a second electrode CAT facing each other, and a plurality of light emitting stacks S1, S2, S3, and S4 between the first electrode AND and the second electrode CAT. The light emitting device may include charge generation layers CGL1, CGL2, and CGL3 between adjacent light emitting stacks among the plurality of light emitting stacks S1, S2, S3, and S4.

The first electrode AND may act as an anode and the second electrode CAT may act as a cathode.

At least one of the first electrode AND and the second electrode CAT is transparent or semi-transparent, and transmit light generated in the light emitting device through the transparent or semi-transparent electrode. For example, when the first electrode AND includes a reflective electrode and the second electrode CAT includes a semi-transparent or transparent electrode, the light emitting device may emit light through the second electrode CAT. As another example, when the first electrode AND includes a transparent electrode and the second electrode CAT includes a reflective electrode, the light emitting device may emit light through the first electrode AND. As another example, the first electrode AND and the second electrode CAT may be transparent or semi-transparent electrodes, so that the light emitting device ED1 may emit light in both directions of the first electrode AND and the second electrode CAT.

The first electrode AND may be connected to the thin film transistor of the pixel circuit at at least one of a plurality of subpixels on the substrate. The pixel circuit is disposed at each of the plurality of subpixels and includes at least one transistor. The second electrode CAT may be provided in common to each subpixel and may receive a common voltage signal at least from the outside.

Each charge generation layer CGL1, CGL2, and CGL3 may include an n-type charge generation layer NCGL and a p-type charge generation layer PCGL. The n-type charge generation layer NCGL generates electrons and supplies the electrons to adjacent light emitting stacks, and the p-type charge generation layer PCGL generates holes and supplies the holes to adjacent light emitting stacks.

The example illustrated in FIG. 1 shows an example in which four light emitting stacks S1, S2, S3, and S4 are disposed between the first electrode AND and the second electrode CAT, but the embodiments of the present disclosure are not limited thereto. That is, the light emitting devices of the embodiments of the present disclosure may include two light emitting stacks, three or more light emitting stacks, or five or more light emitting stacks between the first electrode AND and the second electrode CAT. When two or more light emitting stacks are included in the light emitting devices of the embodiments of the present disclosure, one light emitting stack may include a green light emitting layer GEML.

The light emitting device of FIG. 1 shows an example in which the first light emitting stack S1 (or referred to as a red light emitting stack) includes a red light emitting layer REML, the second light emitting stack S2 (or referred to as a first blue light emitting stack) includes a first blue light emitting layer BEML1, the third light emitting stack S3 (or referred to as a green light emitting stack) includes a green light emitting layer GEML, and the fourth light emitting stack S4 (or referred to as a second blue light emitting stack) includes a second blue light emitting layer BEML2.

As such, the light emitting device ED including light emitting stacks S1, S2, S3, and S4 that emit light with different colors emits white light through at least one of the first electrode AND and the second electrode CAT.

Each of the first to fourth light emitting stacks S1 has a hole transport common layer CML11, CML12, CML13, CML14 on the lower side of the light emitting layer REML, BEML1, GEML, BEML2 and an electron transport common layer CML21, CML22, CML23, CML24 on the upper side of the light emitting layer.

The hole transport common layers CML11, CML12, CML13, CML14 may include a hole injection layer, a hole transport layer (see HTL of FIG. 2), an electron blocking layer, or the like. The hole injection layer may be optionally provided on the first light emitting stack S1 in contact with the first electrode AND. In this case, the hole injection layer may function to transmit holes from the first electrode AND to the red light emitting layer REML. The hole transport layer may transfer holes supplied from the first electrode AND or the charge generation layers CGL1, CGL2, and CGL3 to each of the light emitting layers REML, BEML1, GEML, BEML2. The electron blocking layer may function to block electrons from passing from the light emitting layers REML, BEML1, GEML, BEML2 to the hole transport common layers CML11, CML12, CML13, CML14. For example, the red light emitting stack S1 comprising the red light emitting layer REML, a first charge generation layer CGL1, the first blue light emitting stack S2 comprising the first blue light emitting layer BEML1, and a second charge generation layer CGL2 may be disposed between the first electrode AND and a hole transport layer CML13 of the green light emitting stack S3. For example, the hole transport layer CML13 of the green light emitting stack S3 may contact the p-type charge generation layer of the second charge generation layer CGL2.

The electron blocking layer may or may not be provided selectively in each of the light emitting stacks S1, S2, S3, and S4.

In some cases, a separate optical compensation layer or hole transport auxiliary layer may be provided in addition to the hole transport layer or electron blocking layer between the first electrode AND or the charge generation layer CGL1, CGL2, and CGL3, and each of the light emitting layers REML, BEML1, GEML, BEML2.

The hole transport common layer CML11, CML12, CML13, CML14 may include a hole transport material. At least one of the hole transport common layers CML11, CML12, CML13, CML14 may include a plurality of layers including different materials.

The electron transport common layer CML21, CML22, CML23, CML24 may include a hole blocking layer, an electron transport layer (see ETL in FIG. 2), and an electron injection layer. The electron injection layer may be optionally provided in the fourth light emitting stack S4 in contact with the second electrode CAT. In this case, the electron injection layer functions to inject electrons from the second electrode CAT in the direction of the second blue light emitting layer BEML2. The electron transport layer ETL functions to transfer electrons from the second electrode CAT in each light emitting stack in the direction of each light emitting layer. The hole blocking layer functions to restrict holes injected into the light emitting layer from escaping in the direction of the electron transport layer. For example, a third charge generation layer CGL3 and the second blue light emitting stack S4 comprising the second blue light emitting layer BEML2, which are disposed between an electron transport layer CML23 of the green light emitting stack S3 and the second electrode CAT. For example, the electron transport layer CML23 of the green light emitting stack S3 may contact the n-type charge generation layer of the third charge generation layer CGL3.

The hole blocking layer may or may not be optionally provided in each light emitting stack.

The electron transport common layers CML21, CML22, CML23, CML24 may include an electron transport material. At least one of the electron transport common layers CML21, CML22, CML23, CML24 may be provided in multiple layers including different materials.

The light emitting device of FIG. 1 is implemented as an example in which the first light emitting stack is a red light emitting stack that emits red light, the second light emitting stack is a first blue light emitting stack that emits blue light, the third light emitting stack is a green light emitting stack that emits green light, and the fourth light emitting stack is a second blue light emitting stack that emits blue light, that is, the R/B1/G/B2 light emitting stack is laminated and disposed in a direction from the first electrode AND to the second electrode CAT, but the light emitting devices of the embodiments of the present disclosure are not limited thereto. For example, when a plurality of light emitting stacks are disposed between the first and second electrodes, unlike the example illustrated in FIG. 1 where they are disposed by color, a red light emitting stack, a green light emitting stack, and first and second blue light emitting stacks (R/G/B1/B2) may be sequentially disposed between the first and second electrodes, or a green light emitting stack, a red light emitting stack, and first and second blue light emitting stacks (G/R/B1/B2) may be sequentially disposed between the first and second electrodes, or a first blue light emitting stack, a red light emitting stack, a green light emitting stack, and a second blue light emitting stack (B1/R/G/B2) may be sequentially disposed between the first and second electrodes, or these stacks may be disposed in another order.

Here, two blue light emitting stacks are disposed in the light emitting device so as to compensate for the relatively low blue efficiency compared to other colors. When two blue light emitting stacks are provided between the first and second electrodes AND and CAT, the second blue light emitting layer BEML2 closer to the second electrode CAT may be thicker than the first blue light emitting layer BEML1 closer to the first electrode AND. This compensates for the efficiency of the second blue light emitting layer BEML2 located at the rear of the first electrode AND.

The light emitting device including the first to fourth light emitting stacks S1, S2, S3, and S4 described above emits white light when a voltage greater than a predetermined level is applied between the first electrode AND and the second electrode CAT. Each subpixel may further include a color filter outside the first electrode or the second electrode from which light is emitted, so that each subpixel renders a different color.

Meanwhile, green has the best visibility and is responsible for the greatest luminance when expressing white, so among the different light emitting stacks, the green light emitting stack requires higher luminance efficiency than the other color light emitting stacks. Accordingly, the green light emitting layer GEML of the green light emitting stack may be thicker and have a larger doping amount than the light emitting layers REML, BEML1, BEML2 of the other color light emitting stacks.

In addition, the green light emitting layer GEML may include a phosphorescent material to increase efficiency.

Referring to FIG. 2, the configuration of the light emitting stack including the green light emitting layer GEML that emits green light will be described.

The green light emitting stack may include a hole transport layer HTL, a green light emitting layer GEML, and an electron transport layer ETL sequentially disposed.

The green light emitting layer GEML includes a host mixture including a hole transport host GHH and an electron transport host GEH to facilitate injection and movement characteristics of holes and charges, and includes a green dopant GD in the host mixture.

FIG. 2 separately shows an energy band diagram of the two materials for the hole transport host GHH and the electron transport host GEH. In fact, the hole transport host GHH and the electron transport host GEH are not separated but are mixed at a predetermined ratio in the green light emitting layer GEML. Here, the ratio of the hole transport host GHH and the electron transport host GEH means a volume ratio. In addition, the content of the green dopant GD is smaller than the total content of the hole transport host GHH and the electron transport host GEH. For example, the green dopant GD in the green light emitting layer GEML may be present in an amount of 5 wt % to 25 wt % with respect to the total weight of the green light emitting layer GEML.

The green dopant GD is present in a predetermined amount in a common host including a hole transport host GHH and an electron transport host GEH. Therefore, when the green light emitting layer GEML is observed at different vertical heights between the hole transport layer HTL and the electron transport layer ETL, the content ratios of the hole transport host GHH, the electron transport host GEH, and the green dopant GD at each vertical height may be similar or substantially the same.

As shown in FIG. 1, when the green light emitting stack is disposed in the third light emitting stack S3 and is spaced by a predetermined distance from the first electrode AND, the content of the hole transport host GHH may be greater than the content of the electron transport host GEH so that the recombination region within the green light emitting layer GEML may be adjusted. For example, a content ratio of the hole transport host GHH to the electron transport host GEH in the green light emitting layer GEML may be 7:3. In the green light emitting layer GEML of the third light emitting stack S3 which is farther from the first electrode AND than the second electrode CAT, the content of the hole transport host GHH in the green light emitting layer GEML is larger than that of the electron transport host GEH, so that the region where recombination of holes and electrons occurs is not biased toward the interface between the hole transport layer and the green light emitting layer, but is located within the green light emitting layer GEML.

The content ratio of the hole transport host GHH to the electron transport host GEH in the green light emitting stack GEML may be adjusted in consideration of the distance from the first electrode AND or the second electrode CAT, the thickness of the green light emitting layer GEML, and the distance from the n-type charge generation layer NGCL or the p-type charge generation layer PCGL of the adjacent charge generation layer. The content ratio of the hole transport host GHH to the electron transport host GEH in the green light emitting stack GEML may be adjusted in the range of 1:9 to 9:1.

In the green light emitting layer GEML of the embodiments of the present disclosure, as shown in FIGS. 2 and 3B, the green dopant GD has a deep HOMO energy level and the HOMO energy level HOMO_GD of the green dopant GD is lower than the HOMO energy level HOMO_GHH of the hole transport host GHH in the green light emitting layer GEML. (HOMO_GD<HOMO_GHH). A HOMO energy level of the green dopant has a difference of 0.15 eV or less from the HOMO energy level of the hole transport host.

A content of the green dopant GD in the green light emitting layer GEML may be higher than a content of a red dopant RD, a first blue dopant BD1 and a second blue dopant BD2 in each of the red light emitting layer REML, the first blue light emitting layer BEML1, and the second blue light emitting layer BEML2.

In addition, as shown in FIG. 2, the HOMO energy level HOMO_GD of the green dopant GD is higher than the HOMO energy level HOMO_GEH of the electron transport host GEH (HOMO_GD>HOMO_GEH).

The HOMO energy level HOMO_GEH of the electron transport host GEH is higher than the HOMO energy level HOMO_ETL of the electron transport layer ETL adjacent to the green light emitting layer GEML and is lower than the HOMO energy level of the green dopant GD having a deep HOMO energy level. Here, the HOMO energy level of the electron transport host GEH has a small difference of about 0.25 eV to 0.55 eV from the HOMO energy level of the green dopant GD.

Meanwhile, the electron transport host GEH has a LUMO energy level similar to the LUMO energy level of the hole transport host GHH and has a wide energy band gap.

Here, the electron transport host GEH has the widest energy band gap among the materials contained in the green light emitting layer GEML.

The LUMO energy level of the electron transport host GEH is closer to the LUMO energy level LUMO_GHH of the hole transport host GHH than to the LUMO energy level LUMO_ETL of the electron transport layer ETL.

The HOMO energy level HOMO_GEH of the electron transport host GEH is closer to the HOMO energy level HOMO_ETL of the electron transport layer ETL than to the HOMO energy level HOMO_GD of the green dopant GD.

Specifically, referring to FIGS. 3A and 3B, the hole transport behaviors of the green light emitting layer including the first green dopant GD1 with high HOMO energy level characteristics and the green dopant GD with low HOMO energy level characteristics, compared to the HOMO energy level HOMO_GHH of the hole transport host GHH will be described

FIG. 3A shows use of a first green dopant GD1 having a lower HOMO energy level than the HOMO energy level HOMO_GHH of the hole transport host GHH.

The HOMO energy level HOMO_GD of the green dopant GD of the embodiment of the present disclosure according to FIG. 3B is lower than the HOMO energy level HOMO_GD1 of the green dopant (hereinafter, the first green dopant GD1) having a general hole trap characteristic shown in FIG. 3A. The green dopant GD according to the embodiment of the present disclosure may have a HOMO energy level lower than the HOMO energy level HOMO_HTL of the adjacent hole transport layer HTL, as in FIGS. 2 and 3B (HOMO_GD<HOMO_HTL).

The HOMO energy level HOMO_GHH of the hole transport host GHH is similar to or lower than the HOMO energy level HOMO_HTL of the adjacent hole transport layer HTL. Since the green dopant GD has a HOMO energy level lower than that of the hole transport host GHH, it also has a lower HOMO energy level than the HOMO energy level HOMO_HTL of the adjacent hole transport layer HTL. Therefore, electrons injected from the hole transport layer HTL to the green light emitting layer GEML may be dispersed and moved to the green dopant GD, the hole transport host GHH, and the electron transport host GEH having a lower HOMO energy level than the HOMO energy level HOMO_HTL of the hole transport layer HTL, and the hole transport host GHH with high hole mobility along with the green dopant GD may be used as a path for hole movement. In addition, recombination of holes and electrons may occur in each material, i.e., the hole transport host GHH, the electron transport host GEH, and the green dopant GD, in the green light emitting layer GEML, thereby enhancing exciton formation and improving the recombination efficiency of holes and electrons.

Referring to FIG. 3A, a general first green dopant GD1 has a HOMO energy level higher than the HOMO energy level HOMO_GHH of a hole transport host GHH (HOMO_GD1>HOMO_GHH). In this case, holes are trapped in the area having a higher HOMO energy level, so that when holes are injected from the hole transport layer to the green light emitting layer, the holes are trapped in the first green dopant GD1. This hole trapping behavior causes holes to be charged in the first green dopant GD1 of the green light emitting layer, and it is difficult to completely discharge carriers when switched from an on state to an off state (black state). In addition, when switched from the off state to a low-grayscale state, carriers that remain without being discharged in the green light emitting layer may cause weak light emission. In particular, when a plurality of different color light emitting stacks are laminated, if the hole trapping in the green light emitting layer is increased, and an image defect in which green light is flashed immediately after switching from the off state (black state) to the low-grayscale gray color may be observed. In addition, the holes trapped in the first green dopant GD1 may reduce the efficiency of recombination with electrons in the green light emitting layer. This causes an increase in the driving voltage in the on state and a decrease in luminous efficacy.

The light emitting device according to the embodiment of the present disclosure aims to solve the above-described problem using a green dopant having a HOMO energy level lower than that of the hole transport host GHH to prevent the hole trapping tendency in the green light emitting layer. That is, referring to FIG. 3B, the light emitting device according to the embodiment of the present disclosure includes a green dopant GD having a HOMO energy level HOMO_GD lower than the HOMO energy level HOMO_GHH of the hole transport host GHH in the green light emitting layer GEML. That is, the HOMO energy level of the hole transport host GHH in the green light emitting layer GEML is designed to be higher than the HOMO energy level of the green dopant GD, so that when holes are transferred from the hole transport layer HTL to the green light emitting layer GEML, the influence of the hole transport host GHH is greater than that of the green dopant GD. Therefore, when holes are transferred from the hole transport layer HTL to the green light emitting layer GEML, the hole trapping from the green light emitting layer to the green dopant is prevented or reduced, and holes are dispersed to the hole transport host GHH with a relatively high HOMO energy level, resulting in hole injection. Multi-pass hole transfer mediated by the hole transport host GHH along with the green dopant GD occurs, thus presenting or reducing the phenomenon in which holes accumulate or build up in a specific material.

Meanwhile, the green dopant GD and the first green dopant GD1 according to the embodiment of the present disclosure are each an iridium-based phosphorescent dopant. The green dopant GD according to the embodiment of the present disclosure is phosphorescent dopant. The green dopant GD according to the embodiment of the present disclosure may include an iridium complex. The green dopant GD may include iridium as a core and an electron withdrawing group, such as a cyanide group (—CN) or a fluorine group (—F) to increase the low HOMO energy level and mobility. For example, the phosphorescent dopant backbone may include an iridium compound such as Ir(ppy)3 (Tris(2-phenylpyridine)iridium(III)) or Ir(ppy)2(acac). The green dopant GD according to the embodiment of the present disclosure has both high hole mobility and high electron mobility. Referring to the drawings below, the hole mobility of the green dopant GD and the first green dopant GD1 according to the embodiment of the present disclosure will be described in a HOD (hole only device), and the electron mobility will be described in an EOD (electron only device).

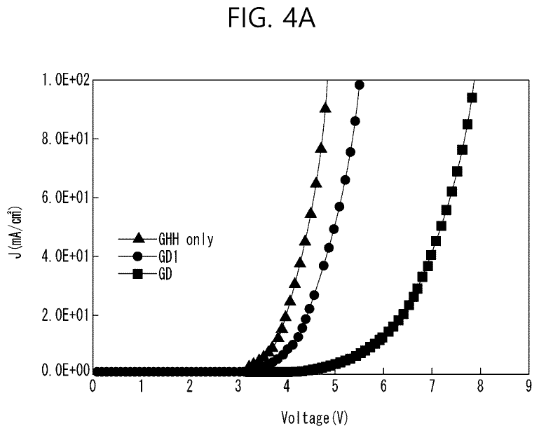

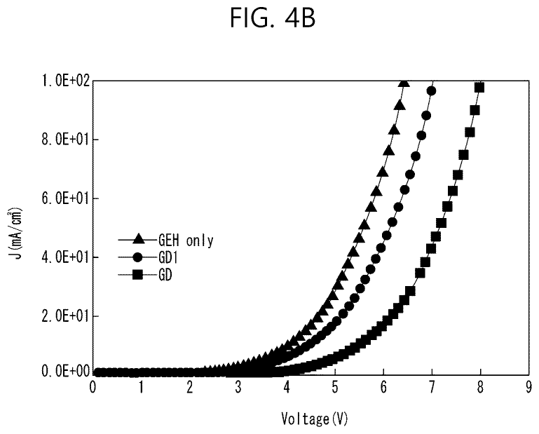

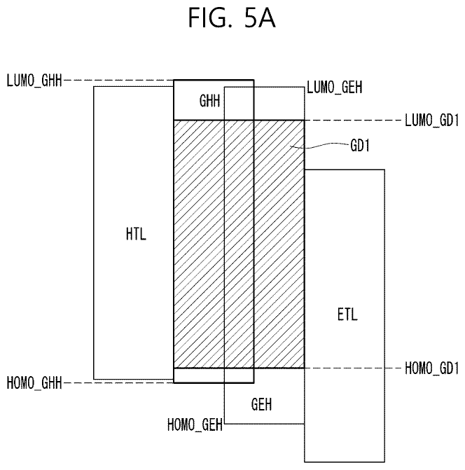

FIG. 4A is a graph showing the JV characteristics of the HOD device when the active layer includes the hole transport host GHH, the first green dopant GD1, and the green dopant GD of the embodiment of the present disclosure. FIG. 4B is a graph showing the JV characteristics of the EOD device when the active layer includes the electron transport host GEH, the first green dopant GD1, and the green dopant GD of the embodiment of the present disclosure.

The electrical characteristics related to the holes of the active layer will be described in the HOD device including a hole injection layer, a first hole transport layer, an active layer, and a second hole transport layer between the first electrode and the second electrode.

As shown in FIG. 4A, when only the hole transport host GHH is included in the active layer of the HOD device and when the green dopant GD of the embodiment of the present disclosure is included in the active layer of the HOD device, the current density characteristics for the driving voltage have a similar tendency. However, when the first green dopant GD1 of FIG. 3A is included in the active layer of the HOD device, the current density is significantly lowered at the same driving voltage. That is, the hole mobility of the green dopant GD of the embodiment of the present disclosure is greater in than of the first green dopant GD1.

The electrical characteristics related to electrons of the active layer will be described in the EOD device having a structure including a first electron injection layer, a first electron transport layer, an active layer, a second electron transport layer, and a second electron injection layer between the first electrode and the second electrode.

As shown in FIG. 4B, when only the electron transport host GEHA is included in the active layer of the EOD device and when the green dopant GD of the embodiment of the present disclosure is included in the active layer of the EOD device, the current density characteristics for the driving voltage show a similar tendency. However, when the first green dopant GD1 of FIG. 3A is included in the active layer of the EOD device, the current density is significantly lowered at the same driving voltage. That is, the electron mobility of the green dopant GD of the embodiment of the present disclosure is greater than that of the first green dopant GD1.

As can be seen from FIG. 3A, the first green dopant GD1 not only has a higher HOMO energy level than the hole transport host GHH, but also has a very low hole mobility, as shown in FIG. 4A, so that the hole trapping characteristic is large. As shown in FIG. 4B, electron trapping or scattering occurs. The first green dopant GD1 has a current density of 10 mA/cm² or more only when the driving voltage is as high as 5 to 6V. Therefore, the current of holes and electrons is delayed compared to the green dopant GD of the present disclosure.

As such, it can be seen that the green dopant according to the embodiment of the present disclosure has a low HOMO energy level, a hole mobility similar to that of the hole transport host, and an electron mobility similar to that of the electron transport host.

That is, when the green dopant according to the embodiment of the present disclosure is included in the green light emitting layer, the charge mobility increases, so that rapid discharge of carriers is possible in the green light emitting layer when the light emitting device is turned off, and the problem of increased electrostatic capacity caused by carrier accumulation may also be solved. In addition, when rapid discharge is completed in the green light emitting layer in the off state, rapid charging is possible when switched to the on state and thus the flashing phenomenon caused by residual carriers in the light emitting device may be eliminated.

Hereinafter, Experimental Examples 1 to 4 of structures in which materials for the green dopant and the electron transport host in the green light emitting layer are different will be described and the difference in characteristics due to the difference in the HOMO energy level of the green dopant and the electron transport host in the light emitting device according to the embodiment of the present disclosure will be described.

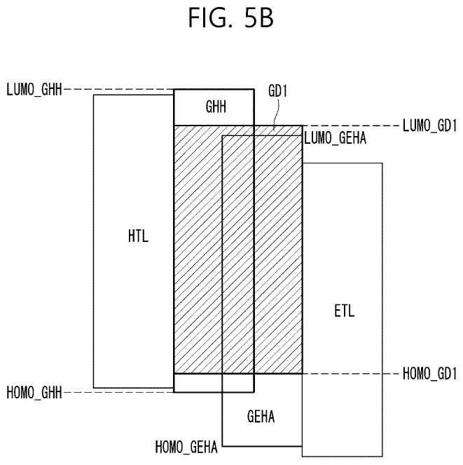

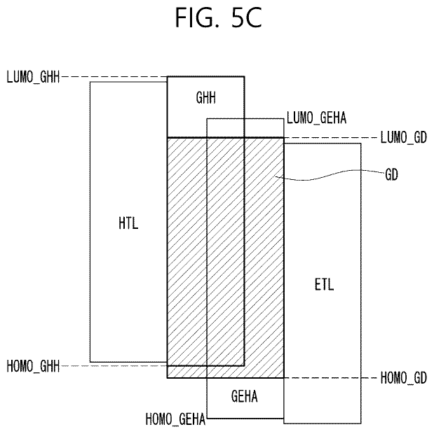

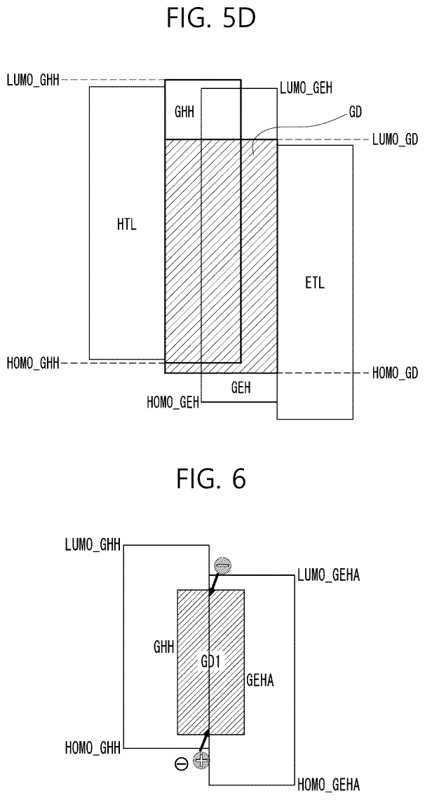

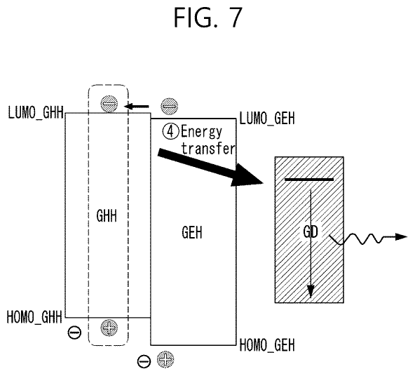

FIGS. 5A to 5D are energy band diagrams of Experimental Examples 1 to 4 in which the materials of the green dopant and the electron transport host in the green light emitting layer in the green light emitting stack are different. FIG. 6 shows movement of carriers to the first green dopant in the green light emitting layer including the hole transport host, the first electron transport host, and the first green dopant of the light emitting device according to Experimental Example 1. FIG. 7 shows movement of carriers to the green dopant in the green light emitting layer including the hole transport host, the electron transport host, and the green dopant of the light emitting device according to the embodiment of the present disclosure.

In the experiments below, the content ratio of the hole transport host GHH to the electron transport host (GEH or GEHA) was set to 7:3.

Experimental Examples 1 to 4 include a hole transport host GHH in common.

The green light emitting layer of Experimental Example 1 EX1 of FIG. 5A includes, as shown in FIG. 3A, a first green dopant GD1 having a HOMO energy level higher than the HOMO energy level of the hole transport host GHH, and a first electron transport host GEHA having a lower HOMO energy level than the HOMO energy level of the first green dopant GD1, but similar to the HOMO energy level of the electron transport layer ETL adjacent to the green light emitting layer.

The green light emitting layer of Experimental Example 2 EX2 of FIG. 5B includes, as shown in FIG. 3A, a first green dopant GD1 having a HOMO energy level higher than the HOMO energy level of the hole transport host GHH, and as shown in FIG. 5B, an electron transport dopant GEH having a HOMO energy level lower than the HOMO energy level of the first green dopant GD1 but approximately 0.14 eV higher than the HOMO energy level of the first electron transport host GEHA of FIG. 5A.

Experimental Example 3 EX3 of FIG. 5C includes a green dopant GD having a lower HOMO energy level than the HOMO energy level of the hole transport host GHH, as shown in FIG. 3B, and a first electron transport host GEHA having a lower HOMO energy level than the HOMO energy level of the green dopant GD but similar to the HOMO energy level of the electron transport layer ETL adjacent to the green light emitting layer, as shown in FIG. 5C.

Experimental Example 4 EX4 of FIG. 5D includes a green dopant GD having a lower HOMO energy level than the HOMO energy level of the hole transport host GHH, as shown in FIG. 3B, and an electron transport dopant GEH having a lower HOMO energy level than the HOMO energy level of the green dopant GD but higher by approximately 0.14 eV than the HOMO energy level of the first electron transport host GEHA of FIG. 5A, as shown in FIG. 5D. Experimental Example 4 EX4 of FIG. 5D corresponds to the light emitting device of the embodiment of the present disclosure described with reference to FIGS. 1 to 2 and FIG. 3B.

In the green light emitting layers of Experimental Examples 1 to 4, the hole transport host GHH, the first green dopant GD1, the green dopant GD, the first electron transport host GEHA, and the electron transport host GEH with the HOMO energy level and LUMO energy level characteristics shown in Table 1 were used in the experiments.

TABLE 1

| | HOMO [eV] | LUMO [eV] |
|---|---|---|
| GHH | −5.14 | −2.04 |
| GEHA | −5.70 | −2.50 |
| GEH | −5.56 | −2.12 |
| GD1 | −5.13 | −2.60 |
| GD | −5.22 | −2.66 |

Referring to Table 1, Experimental Example 1 EX1 has a difference of 0.57 eV between the HOMO energy level of the first green dopant GD1 and the HOMO energy level of the first electron transport host GEHA. Experimental Example 2 EX2 has a difference of 0.43 V between the HOMO energy level of the first green dopant GD1 and the HOMO energy level of the electron transport host GEH. Experimental Example 3 EX3 has a difference of 0.48 eV between the HOMO energy level of the green dopant GD and the HOMO energy level of the first electron transport host GEHA. Experimental Example 4 EX4 has a difference of 0.34 eV between the HOMO energy level of the green dopant GD and the HOMO energy level of the electron transport host GEH.

Experimental Example 1 EX1 and Experimental Example 2 EX2 have the difference in HOMO energy levels when the HOMO energy levels of the materials for the electron transport hosts GEHA and GEH are different when the first green dopant GD1 has a higher HOMO energy level than the hole transport host GHH, and Experimental Example 3 EX3 and Experimental Example 4 EX4 have the difference in HOMO energy levels when the HOMO energy levels of the materials for the electron transport hosts GEHA and GEH are different when the green dopant GD has a lower HOMO energy level than the hole transport host GHH.

In Experimental Examples 3 and 4 EX3 and EX4, by introducing a green dopant having a low HOMO energy level, holes trapped in the green dopant in the green light emitting layer are reduced, carrier behavior appears under conditions where the influence of the hole transport host is large, and the hole transport host along with the green dopant acts as a hole transport medium, increasing the exciton generation efficiency.

As shown in FIG. 6, in Experimental Example 1 EX1, holes are directly injected into the first green dopant GD1 based on the HOMO energy level of the hole transport host and electrons are directly injected into the first electron transport host based on the LUMO energy level of the first electron transport host.

The difference in HOMO energy level between the hole transport host GHH and the first electron transport host GEHA is as large as 0.56 eV, which limits the movement of holes to the first electron transport host GEHA after holes are injected into the first green dopant GD1. The difference in LUMO energy level between the hole transport host GHH and the first electron transport host GEHA is also about 0.5 eV, so electrons injected into the first electron transport host GEHA in the electron transport layer do not move to the hole transport host GHH but are directly injected into the first green dopant GD1.

In Experimental Example 1 EX1, after holes and electrons are directly injected into the first green dopant GD1, the movement of the holes and electrons from the first green dopant GD1 back to the hole transport host GHH or the first electron transport host GEHA is restricted due to the carrier trap property of the first green dopant GD1, which reduces the exciton generation efficiency in the green light emitting layer and may therefore reduce the luminous efficacy. In addition, when holes and electrons trapped in the dopant are not formed as excitons but present as residual carriers, complete discharge is difficult in the off state and there is a flash of green light when switched from the off state to a low-grayscale state.

As shown in FIG. 7, the light emitting device according to the embodiment of the present disclosure (see Experimental Example 4 of FIG. 5D) has a structure in which holes injected into the hole transport host GHH may be easily moved to the electron transport host GEH due to the small HOMO energy level difference between the two hosts, which corresponds to 0.32 eV between the hole transport host and the electron transport host. In each of green light emitting layers of Experimental Examples 1 to 4 EX1 to EX4, the hole transport host GHH and the electron transport host GEHA, GEH are present at a content ratio of 7:3. In addition, the green light emitting layer of Experimental Example 4 EX4 includes a green dopant GD having a deep HOMO energy level in the host mixture of the hole transport host GHH and the electron transport host GEH at the content ratio of 7:3.

When holes are injected into the green light emitting layer based on the green dopant GD having a low (deep) HOMO energy level, the holes are transferred not only to the green dopant GD but also to the hole transport host GHH present in a larger content ratio. In addition, the difference in LUMO energy level between the hole transport host GHH and the electron transport host GEH is less than 0.1 eV, so that holes easily move to the LUMO energy level of the hole transport host GHH through the LUMO energy level of the electron transport host GEH. Therefore, holes and electrons may be transferred together in the hole transport host GHH in a large content in the green light emitting layer to generate excitons, and the excitons generated in the hole transport host are energy-transferred to the green dopant, and finally, the excitons in the green dopant fall to the ground state, thereby emitting green light.

As such, the light emitting device according to the embodiment of the present disclosure is capable of improving the green light emitting efficiency compared to Experimental Example 1 EX1 described above, and minimizing or reducing residual carriers in the green light emitting layer, thus contributing to the formation of excitons by recombination of holes and electrons.

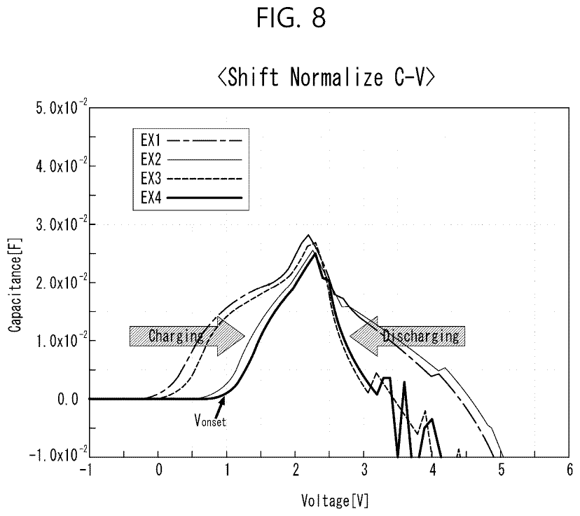

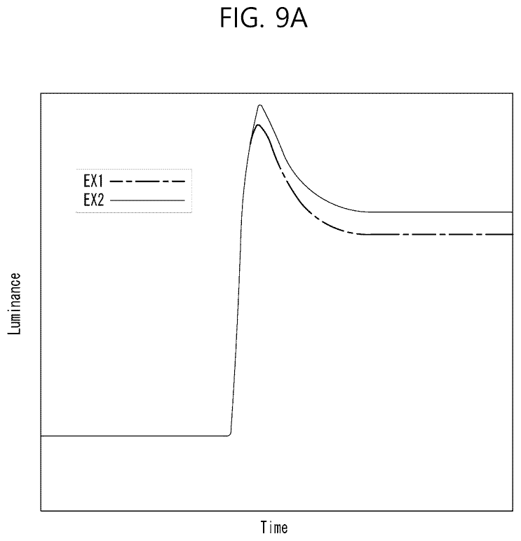

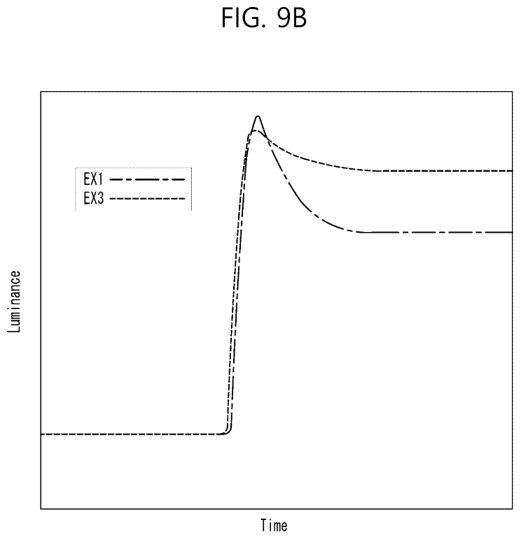

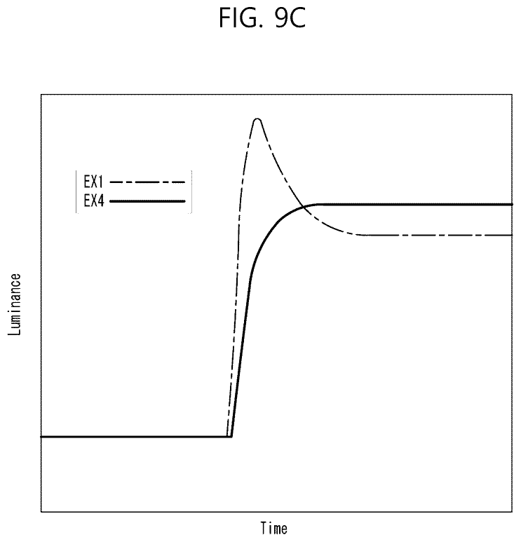

FIG. 8 is a graph showing the CV characteristics of the green light emitting stacks of Experimental Examples 1 to 4. FIGS. 9A to 9C are graphs showing the luminance when switched from a black state to a low-grayscale state of Experimental Examples 2 to 4 compared to Experimental Example 1.

Referring to FIG. 8, the area of each C-V graph for Experimental Examples 1 to 4 EX1, EX2, EX3, EX4 is proportional to the amount of carriers accumulated in the light emitting layer when a voltage is applied.

Experimental Example 1 EX1 has a first green dopant GD1 having a higher HOMO energy level that is than the HOMO energy level of the hole transport host GHH and a first electron transport host GEHA having a HOMO energy level that is lower than the HOMO energy level of the first green dopant GD1 but is similar to the HOMO energy level of the electron transport layer. The carrier charging phenomenon occurs immediately after the voltage is applied and the area of the C-V graph is large, which means that the amount of carriers that should be discharged in the green light emitting layer is large when switched from the on state to the off state, making it difficult to completely discharge or taking time to completely discharge.

In Experimental Example 2 EX2, the electron transport host GEH has a wider energy band gap than the first electron transport host GEHA but a relatively high HOMO energy level, and the onset voltage (Vonset), at which the capacitance changes in response to the applied voltage, is designed to be larger compared to Experimental Example 1 EX1, so that the carrier charging phenomenon that occurs immediately after the voltage is applied can be solved. Here, the electron transport host GEH has a moiety EA having bipolarity or a weak hole transport property of weak hole mobility, and has relatively slow hole transport property compared to the first electron transport host GEHA, and can delay the phenomenon in which hole carriers are charged in the green light emitting layer. In addition, the wide energy band gap of the electron transport host may delay injection of electrons from the electron transport layer to the green light emitting layer, thereby delaying the phenomenon in which electron carriers are charged in the green light emitting layer. This carrier charging reduction and delay effect of the electron transport host GEH may be also obtained in Experimental Example 4 EX4.

Experimental Example 3 EX3 includes a first electron transport host GEHA, a green dopant GD, and the first electron transport host GEHA in the green light emitting layer. Specifically, the green dopant has a HOMO energy level lower than that of the hole transport host GHH. In this case, holes are not trapped in the green dopant GD, but move through the hole transport host GHH contained in a large amount in the green light emitting layer, and may be utilized to form excitons in the hole transport host GHH, thereby preventing accumulation of carriers in the light emitting layer and enhancing the discharge effect when switched from the on state to the off state. The effect of the green dopant GD having such a low HOMO energy level may also be achieved in Experimental Example 4 EX4.

That is, the light emitting device according to the embodiment of the present disclosure, like Experimental Example 4 EX4, includes a green dopant GD having a HOMO energy level lower than that of the hole transport host GHH, thus providing smooth discharge of carriers when switched from an on state to an off state, and includes an electron transport host GEH having a LUMO energy level similar to that of the hole transport host GHH and a HOMO energy level lower than that of the green dopant GD, and thus has a wide energy level, thus solving the problem in which flashing is caused by carriers charged immediately after switching from an off state to an on state.

Table 2 below compares the green efficiencies between Experimental Examples 1 to 4 EX1, EX2, EX3, EX4.

TABLE 2

| Item | EX1 | EX2 | EX3 | EX4 |
|---|---|---|---|---|
| Green dopant | GD1 | GD1 | GD | GD |
| Electron transport host | GEHA | GEH | GEHA | GEH |
| Green efficiency (%) | 100 | 105 | 102 | 119 |

As can be seen from Table 2, the green efficiency increases significantly as the difference in HOMO energy level between the green dopant and the electron transport host decreases compared to Experimental Example 1 EX1.

In addition, it can be seen that the green efficiency increases in all of Experimental Examples 2 to 4 EX2, EX3, EX4, compared to Experimental Example 1 EX1, but Experimental Example 4 EX4 exhibits a considerable increase in the green efficiency. In particular, it can be seen that the green efficiency of the light emitting device according to the embodiment of the present disclosure is improved when the light emitting device has the configuration of Experimental Example 4 EX4.

Hereinafter, the results of experiments to evaluate the change in luminance when switched from a black state to a low-grayscale state in a structure including a light emitting device of the multiple stack structure of FIG. 1 in each subpixel will be described with reference to Table 3 and FIGS. 9A to 9C.

After the black state is maintained for 2 seconds (2,000 msec), it is switched to a low-grayscale gray at a low-current state of 0.5 μA, and the change in luminance over time was evaluated.

TABLE 3

| | EX1 | EX2 | EX3 | EX4 |
|---|---|---|---|---|
| Peak luminance/average | 159 | 147 | 116 | 106 |
| luminance (%) | | | | |

As shown in FIG. 9A, in Experimental Example 1 EX1, the peak of the luminance occurs immediately after switching from the black state to the low-grayscale state, and then the luminance gradually decreases below the peak value. The period in which the luminance maintains a constant value after a predetermined period of time is referred to as an “average period”. Referring to Table 3, the peak luminance of Experimental Example 1 EX1 corresponds to approximately 159% of the average luminance.

Referring to FIG. 9A, in Experimental Example 2 EX2, the peak luminance occurs immediately after switching from the black state to the low-grayscale state, and then the luminance gradually decreases below the peak luminance. A predetermined period of time after the occurrence of the peak, a constant average luminance is maintained. Referring to FIG. 9A, when comparing the average luminance of Experimental Example 1 EX1 with Experimental Example 2 EX2, the average luminance of Experimental Example 2 EX2 is large. Referring to Table 3, the peak luminance of Experimental Example 2 EX2 corresponds to approximately 147% of the average luminance. Here, it can be seen that the flashing level of Experimental Example 2 EX2 was reduced to less than 10% due to the wide energy band gap of the electron transport host GEH and the reduced HOMO energy level difference with the green dopant. However, in Experimental Example 2 EX2, the first green dopant GD1 had a higher HOMO energy level than the hole transport host GHH, hole trapping occurred in the first green dopant GD1 and thus the flashing phenomenon was not avoided.

Referring to FIG. 9B, in Experimental Example 3 EX3, the peak of luminance occurs immediately after switching from the black state to the low-grayscale state, and then the luminance gradually decreases below the peak value. A predetermined period of time after the peak luminance occurs, the average luminance is maintained. Referring to FIG. 9B, when comparing the average luminance and peak luminance between Experimental Example 1 EX1 and Experimental Example 3 EX3, it can be seen that the average luminance of Experimental Example 3 EX3 is large and the peak luminance is rather small compared to Experimental Example 1 EX1. Therefore, referring to Table 3, the peak luminance of Experimental Example 3 EX3 corresponds to approximately 116% of the average luminance. In Experimental Example 3 EX3, it can be seen that the hole trapping to the green dopant GD is improved using the green dopant GD having a low HOMO energy level.

As can be seen from FIG. 9C, in Experimental Example 4 EX4, the peak of luminance does not occur immediately after switching from a black state to a low-grayscale state, the luminance gradually increases over time when switched to the low-grayscale state, and then a constant saturated average luminance is maintained. In this case, in Experimental Example 4 EX4 according to the embodiment of the present disclosure, the peak luminance occurs in the average luminance range, the average luminance and the peak luminance are similar, and referring to Table 3, Experimental Example 4 EX4 shows a peak luminance of approximately 106% with respect to the average luminance.

That is, it can be seen that the light emitting device and light emitting display device according to the embodiment of the present disclosure, as shown in Experimental Example 4 EX4, include a green dopant GD having a low HOMO energy level and an electron transport host GEH having a wide energy band gap but a relatively small difference from the HOMO energy level of the green dopant GD in a green light emitting layer, so that a phenomenon in which a specific color luminance peak appears after switching from a black state to a low-grayscale state and flashing occurs is prevented. This means that, when holes are injected from the hole transport layer to the green light emitting layer, multiple passes of the green dopant, the hole transport host, and the electron transport host are formed, thereby reducing charging of carriers before the turn-on voltage between the first electrode and the second electrode of the light emitting device and preventing the flashing.

The material contained in the green light emitting layer of the embodiment of the present disclosure will be described.

The green dopant GD and the first green dopant GD1 of the embodiment of the present disclosure are iridium-based phosphorescent dopants, have different substituents, and differ from each other in HOMO energy levels and hole mobility/electron mobility.

That is, the green dopant GD of the embodiment of the present disclosure further includes an electron withdrawing group, such as a cyanide group (—CN) or a fluorine group (—F), in an iridium-based phosphorescent dopant, and thus has a low HOMO energy level. The green dopant GD of the embodiment of the present disclosure has a HOMO energy level that is approximately 0.09 eV lower than that of the first green dopant GD1. In this case, although the HOMO energy level difference between the green dopant GD and the first green dopant GD1 is not large, there is a difference from the HOMO energy level of the hole transport host GHH, and, as described above, there may be a large difference in the movement and function of holes when holes are injected from the hole transport layer to the green light emitting layer.

In addition, since the green dopant GD of the embodiment of the present disclosure has a low HOMO energy level, as shown in FIG. 4A, the hole mobility is superior to that of the first green dopant GD1, and as shown in FIG. 4B, the electron mobility is also superior to that of the first green dopant GD1.

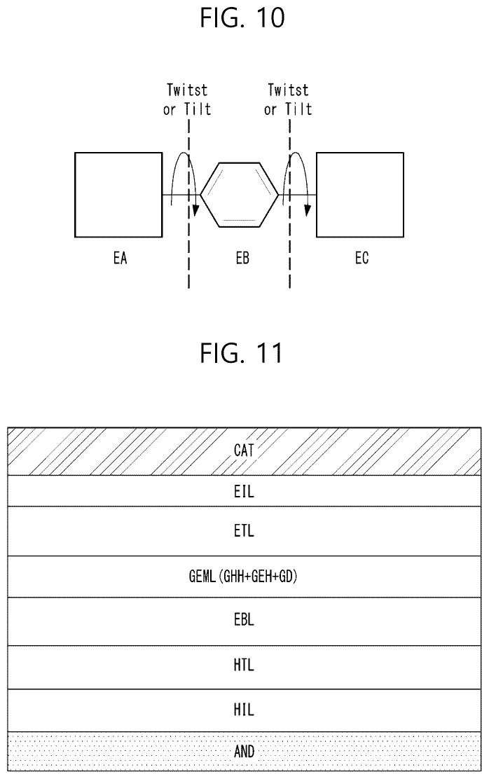

FIG. 10 is a schematic diagram illustrating the electron transport host of the embodiment of the present disclosure.

As shown in FIG. 10, the electron transport host GEH may be formed by bonding a hole transport moiety EA on one side thereof to a strong electron transporting moiety EC on the other side thereof via a linker EB therebetween. Therefore, the electron transport host GEH comprises a bipolar compound and has bipolarity.

The linker EB may be, for example, an arene derivative having 5 or more carbon atoms.

Examples of the hole transport moiety EA may include carbazole derivatives such as biscarbazole and indolocarbazole. In order to ensure the stability of the hole transport moiety EA, one of the hydrogen atoms of the hole transport moiety EA may be replaced with deuterium.

Examples of the electron transport moiety EC may include pyrimidine, pyrazine, pyridazine, triazine, and the like containing two or more nitrogen atoms.

The electron transport host GEH has a LUMO energy level LUMO_GEH similar to the LUMO energy level of the hole transport host GHH and a HOMO energy level HOMO_GEH lower than the HOMO energy level of the green dopant GD, and thus has a wide energy band gap. In order to have a wide energy band gap, the electron transport moiety EC and the hole transport moiety EA are tilted or twisted at a specific angle at the connection portion with the linker EB, thus reducing an effective conjugation of the compound for forming the electron transport host GEH.

Meanwhile, the energy band gap of a material tends to widen as conjugation in the compound constituting the material becomes shorter.

In addition, the electron transport host GEH of the embodiment of the present disclosure has a wider energy band gap than the first electron transport host GEHA to be compared therewith. However, the electron transport host GEH of the embodiment of the present disclosure is twisted or tilted at the connection between the linker EB and the hole transport moiety EA, so that the hole mobility is lowered compared to the compound of the first electron transport host GEHA compared therewith which is relatively flat. The electron transport host GEH of the embodiment of the present disclosure is twisted or tilted at the connection between the linker EB and the electron transport moiety EC, so that the electron mobility is lowered compared to the compound of the first electron transport host GEHA to be compared therewith, which is relatively flat. In addition, the electron transport host GEH of the embodiment of the present disclosure contains a compound in which a hole transport moiety EA and an electron transport moiety EC are linked to the linker EB, thus having bipolarity.

The HOMO energy level and LUMO energy level described herein are evaluated based on the energy level of a vacuum as 0.0 eV and both the HOMO energy level and the LUMO energy level are lower than 0.0 eV and thus have negative values. Upon comparison between two materials, a deeper energy level of one material means that the material has an energy level on the lower side of the energy diagram and has a larger absolute value.

Therefore, the HOMO energy level of the green dopant GD in the green light emitting layer GEML of the embodiments of the present disclosure is lower than the HOMO energy level of the first green dopant GD1 having a general hole trap characteristic and thus has a larger absolute value.

The HOMO energy level HOMO_GD of the green dopant GD is lower than the HOMO energy level HOMO_GHH of the hole transport host GHH and is higher than the HOMO energy level HOMO_GEH of the electron transport host GEH (HOMO_GEH<HOMO_GD<HOMO_GHH).

In this case, when holes are transferred to the green light emitting layer from the hole transport layer HTL adjacent to the green light emitting layer GEML, the holes are not trapped at the relatively low HOMO energy level of the green dopant GD, but are divided and moved to the hole transport host GHH and the green dopant GD of the green light emitting layer GEML, thereby preventing hole charging from becoming severe in the light emitting layer GEML.

In addition, in the embodiments of the present disclosure, the electron transport host GEH in the green light emitting layer GEML has a wide energy band gap, but has a HOMO energy level HOMO_GEH that is higher than the HOMO energy level HOMO_GEH1 of the electron transport host of a general green light emitting layer (hereinafter, the first electron transport host GEH1).

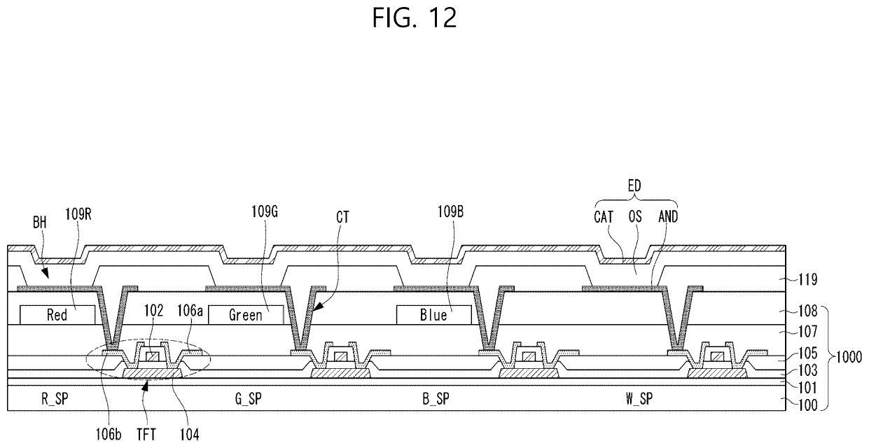

FIG. 11 is a cross-sectional view illustrating a light emitting device according to another embodiment of the present disclosure.

As shown in FIG. 11, a light emitting device according to another embodiment of the present disclosure includes a hole injection layer HIL, a hole transport layer HTL, a green light emitting layer GEML, an electron transport layer ETL, and an electron injection layer EIL between a first electrode AND and a second electrode CAT.

The green light emitting layer GEML includes a hole transport host GHH, an electron transport host GEH, and a green dopant GD described in FIGS. 1 to 2 and FIG. 3B.

Here, the green dopant GD has a lower HOMO energy level than the HOMO energy level of the hole transport host GHH, and the electron transport host GEH has a LUMO energy level that has a difference of 0.15 eV or less from the LUMO energy level of the hole transport host GHH, and has a wide energy band gap having a lower HOMO energy level than the HOMO energy level of the green dopant GD. In addition, the electron transport host GEH has a HOMO energy level that is 0.25 eV to 0.55 eV lower than the HOMO energy level of the green dopant GD.

As a result, the light emitting device of FIG. 11 has an improved light emitting efficiency of the green light emitting layer, and the flashing phenomenon in which green light is observed when switched from the off state to the on state may be prevented due to the improved charge and discharge characteristics of the light emitting device.

Hereinafter, an example in which a light emitting device described above is applied to a light emitting display device will be described.

FIG. 12 is a cross-sectional view illustrating a light emitting display device according to one embodiment of the present disclosure.

As shown in FIG. 12, a light emitting display device according to an embodiment of the present disclosure may emit light through a first electrode AND on an emission side by applying the light emitting device of FIG. 1 at least one of a plurality of subpixels R_SP, G_SP, B_SP, and W_SP.

The light emitting device ED of each subpixel may include a first electrode AND, a second electrode CAT, and an intermediate layer OS. The intermediate layer OS may include a plurality of stacks and have the same configuration in the plurality of subpixels R_SP, G_SP, B_SP, W_SP. In addition, the intermediate layer OS may include the electron transport stack between the plurality of stacks and the charge generation layer.

As shown in FIG. 12, the light emitting display device according to an embodiment of the present disclosure may include a substrate 100 having a plurality of subpixels R_SP, G_SP, B_SP, W_SP, a light emitting device ED commonly provided on the substrate 100, a thin film transistor TFT provided on each of the subpixels R_SP, G_SP, B_SP, W_SP and connected to the first electrode AND of the light emitting device ED, and a color filter layer 109R, 109G, 109B provided under the first electrode AND of at least one of the subpixels.

The example in FIG. 12 shows a case in which a white subpixel W_SP is included in the light emitting display device, but the present disclosure is not limited thereto, and a structure in which the white subpixel W_SP is omitted and only red, green, and blue subpixels R_SP, G_SP, B_SP are provided is also possible. In some cases, a combination of cyan subpixels, magenta subpixels, and yellow subpixels that can express white by replacing red, green, and blue subpixels is also possible.

The thin film transistor TFT includes, for example, a gate electrode 102, a semiconductor layer 104, and a source electrode 106a and a drain electrode 106b connected to both sides of the semiconductor layer 104. In addition, a channel protection layer may be further provided on an upper portion of a portion where a channel of the semiconductor layer 104 is located to prevent direct connection between the source electrode 106a/drain electrode 106b and the semiconductor layer 104. The thin film transistor TFT may include a buffer layer 101 on a substrate 100 and may be located on the buffer layer 101.

A gate insulating film 103 is provided between the gate electrode 102 and the semiconductor layer 104.

The semiconductor layer 104 may be formed of, for example, an oxide semiconductor, amorphous silicon, polycrystalline silicon, or a combination of two or more thereof. For example, when the semiconductor layer 104 is an oxide semiconductor, the heating temperature required to form a thin film transistor may be lowered, so that the substrate 100 may be used with a high degree of freedom, which makes it advantageous for application to a flexible display device.

A gate electrode 102 may be provided on the gate insulating film 103 and an interlayer insulating film 105 may be further provided between the gate electrode 102 and the source electrode 106a/drain electrode 106b.

In addition, the drain electrode 106b of the thin film transistor TFT may be connected to the first electrode AND and the contact hole CT provided in the first and second protective films 107 and 108.

The first protective film 107 is provided primarily to protect the thin film transistor TFT, and a color filter 109R, 109G, 109B may be provided on the first protective film 107.

A second protective film 108 is provided on the first protective film 107 including the color filter 109R, 109G, 109B.

When a plurality of subpixels includes a red subpixel R_SP, a green subpixel G_SP, a blue subpixel B_SP, and a white subpixel W_SP, as shown in FIG. 12, the color filters are provided as first to third color filters 109R, 109G, 109B for the remaining subpixels R_SP, G_SP, B_SP except for the white subpixel W_SP, so as to allow white light emitted through the first electrode AND to pass according to each wavelength. In addition, a second protective film 108 is formed under the first electrode AND to cover the first to third color filters 109R, 109G, 109B. The first electrode AND is formed on the surface of the second protective film 108 excluding the contact hole CT and is connected to one of the drain electrode 106b and the source electrode 106a of the thin film transistor TFT to receive an electrical signal from the thin film transistor TFT.

Here, the thin film transistor array substrate 1000 may include the substrate 100, the thin film transistor TFT, the color filter 109R, 109G, 109B, and the first and second protective films 107 and 108.

The light emitting device ED is formed on a thin film transistor array substrate 1000 including a bank 119 defining a light emitting portion BH. The light emitting device ED may include a transparent first electrode AND, a second electrode CAT of a reflective electrode facing the first electrode AND, and an intermediate layer OS formed between the first electrode AND and the second electrode CAT and may include a plurality of light emitting stacks S1, S2, S3, and S4 and first to third charge generation layers CGL1, CGL2, and CGL3, and a green light emitting layer GEML including a hole transport host GHH, an electron transport host GEH, and a green dopant GD, as shown in FIGS. 2 and 3B in at least one green light emitting stack among the plurality of light emitting stacks S1, S2, S3, and S4 that emits green light.

Here, the green dopant GD has a HOMO energy level lower than the HOMO energy level of the hole transport host GHH, the electron transport host GEH has a LUMO energy level that has a difference of 0.15 eV or less from the LUMO energy level of the hole transport host GHH, and has a wide energy band gap having a HOMO energy level lower than the HOMO energy level of the green dopant GD. In addition, the electron transport host GEH has a HOMO energy level that is 0.25 eV to 0.55 eV lower than the HOMO energy level of the green dopant GD.

As a result, the light emitting device ED of FIG. 12 has an improved light emitting efficiency of the green light emitting layer, and the flashing phenomenon in which green light is observed when switched from the off state to the on state may be prevented due to the improved charge and discharge characteristics of the light emitting device.

The first electrode AND is divided into each subpixel, and the remaining layers excluding the first electrode AND of the light emitting device ED may be provided as an integral part in the entire display area without distinction by subpixel.

Either the first electrode AND or the second electrode CAT may be connected to a thin film transistor TFT.

Meanwhile, the light emitting display device of FIG. 12 described above is illustrated as a structure in which light is emitted downward, but the present disclosure is not limited thereto. For example, the first electrode AND includes a reflective electrode, the second electrode CAT is a transparent electrode or a reflective-transparent electrode, and the color filter is disposed above the second electrode CAT so that the light emitting display device may be applied in a top-emission manner.

In the structure described above, the intermediate layer OS of the light emitting device ED is common to each subpixel, but the light emitting display device of the embodiment of the present disclosure is not limited thereto.

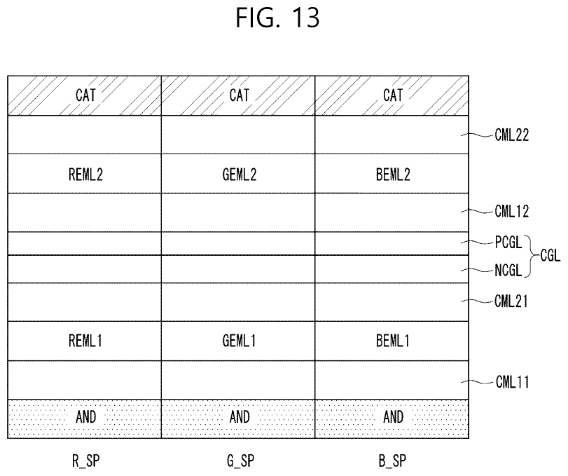

FIG. 13 is a cross-sectional view illustrating a light emitting display device according to another embodiment of the present disclosure.

As shown in FIG. 13, in addition, the light emitting display device according to another embodiment of the present disclosure may include a first electrode AND and a second electrode CAT facing each of a red subpixel R_SP, a green subpixel G_SP, and a blue subpixel B_SP, and a plurality of light emitting stacks between the first electrode AND and the second electrode CAT, wherein the plurality of light emitting stacks has overlapping light emitting layers that emit the same color. That is, the red subpixel R_SP may have red light emitting layers REML1 and REML2 in separate stacks with a charge generation layer CGL disposed therebetween, the green subpixel G_SP may have green light emitting layers GEML1 and GEML2 in separate stacks with a charge generation layer CGL disposed therebetween, and the blue subpixel B_SP may have blue light emitting layers BEML1 and BEML2 in separate stacks with a charge generation layer CGL disposed therebetween.

Here, a common layer CML11 related to hole injection and hole transport is provided between the first electrode AND and the first red light emitting layer REML1, the first green light emitting layer GEML1, and the first blue light emitting layer BEML1, and a common layer CML21 related to electron transport is provided between the first red light emitting layer REML1, the first green light emitting layer GEML1, and the first blue light emitting layer BEML1 and the charge generation layer CGL.

The charge generation layer CGL may be provided by laminating an n-type charge generation layer NCGL and a p-type charge generation layer PCGL.

In addition, a common layer CML12 related to hole injection and hole transport may be provided between the charge generation layer CGL and the second red light emitting layer REML2, the second green light emitting layer GEML2, and the second blue light emitting layer BEML2, and a common layer CML22 including an electron transport layer and an electron injection layer may be provided between the second red light emitting layer REML2, the second green light emitting layer GEML2, and the second blue light emitting layer BEML2 and the second electrode CAT.

The common layers CML11 and CML12 related to hole injection and transport may include at least one of a hole injection layer, a hole transport layer, and an electron blocking layer, and the common layers CML21 and CML22 related to electron transport and injection may include at least one of a hole blocking layer, an electron transport layer, and an electron injection layer.

Here, at least one of the green light emitting layers GEML1 and GEML2 provided in at least a green subpixel G_SP includes the hole transport host GHH, the electron transport host GEH, and the green dopant GD as described in FIG. 2 and FIG. 3B.

Here, the green dopant GD has a lower HOMO energy level than a HOMO energy level of the hole transport host GHH, the electron transport host GEH has a LUMO energy level that has a difference of 0.15 eV or less from a LUMO energy level of the hole transport host GHH, and has a wide energy bandgap having a HOMO energy level lower than a HOMO energy level of the green dopant GD. In addition, the electron transport host GEH has a HOMO energy level that is 0.25 eV to 0.55 eV lower than a HOMO energy level of the green dopant GD.

As a result, the green light emitting device of the green subpixel G_SP may have improved light emitting efficiency of the green light emitting layer, and the green light emitting device may prevent a flashing phenomenon in which green light is observed when switched from an off state to an on state due to improved charging and discharging characteristics.

The light emitting device and the light emitting display device including the same according to the embodiment of the present disclosure have a green dopant GD having a HOMO energy level lower than that of a hole transport host GHH in the green light emitting layer, so that, when holes are injected from the hole transport layer into the green light emitting layer, multiple passes of the green dopant, the hole transport host, and the electron transport host may be formed for hole movement.

Since holes or electrons are not trapped in the green dopant and contribute to exciton formation in each host and dopant, it is possible to prevent a problem of image quality deterioration caused by residual carriers charged in the green light emitting layer.

The light emitting device and the light emitting display device including the same contain a green dopant having a low HOMO energy level and an electron transport host having a small difference in HOMO energy level with the green dopant in the green light emitting layer, so that the onset voltage is higher than a predetermined level, the green layer has C-V characteristics that facilitate carrier charging and discharging, and the image quality deterioration that occurs when the green light emitting layer is switched on and off can be prevented.

The flashing phenomenon in which green emission spikes when switching from an off state to a low-grayscale state due to residual carriers in the green light emitting layer can be prevented or reduced.

The light emitting device and the light emitting display device including the same according to the embodiments of the present disclosure are capable of improving the efficiency of the light emitting layer and reducing the image quality deterioration, thus being continuously applicable and achieving ESG (environmental/social/governance) goals.

A light emitting device according to one embodiment of the present disclosure may comprise a first electrode and a second electrode facing each other and a green light emitting stack comprising a hole transport layer, a green light emitting layer, and an electron transport layer disposed between the first electrode and the second electrode. The green light emitting layer may comprise a hole transport host, an electron transport host, and a green dopant. A HOMO energy level of the green dopant may be lower than a HOMO energy level of the hole transport host and may be higher than a HOMO energy level of the electron transport host. A HOMO energy level of the electron transport host may be higher than the HOMO energy level of the electron transport layer.

In a light emitting display device according to one embodiment of the present disclosure, the HOMO energy level of the hole transport host may be lower than the HOMO energy level of the hole transport layer.

In a light emitting display device according to one embodiment of the present disclosure, a HOMO energy level of the green dopant may have a difference of 0.15 eV or less from the HOMO energy level of the hole transport host.

In a light emitting display device according to one embodiment of the present disclosure, the green dopant may be a phosphorescent dopant and may comprise an iridium and an electron-withdrawing group.

In a light emitting display device according to one embodiment of the present disclosure, the electron transport host may comprise a bipolar compound in which an electron transport moiety and a hole transport moiety are linked to a linker through a first connecting portion and a second connecting portion.

In a light emitting display device according to one embodiment of the present disclosure, a HOMO energy level of the electron transport host may be 0.25 eV to 0.55 eV lower than a HOMO energy level of the green dopant.

In a light emitting display device according to one embodiment of the present disclosure, the electron transport host may have the widest energy band gap among materials contained in the green light emitting layer. The LUMO energy level of the electron transport host may be closer to the LUMO energy level of the hole transport host than to the LUMO energy level of the electron transport layer. The HOMO energy level of the electron transport host may be closer to the HOMO energy level of the electron transport layer than to the HOMO energy level of the green dopant.

In a light emitting display device according to one embodiment of the present disclosure, the green dopant may be contained in an amount of 5 wt % to 25 wt % in the green light emitting layer.

In a light emitting display device according to one embodiment of the present disclosure, the light emitting device may further comprise a red light emitting stack comprising a red light emitting layer, a first charge generation layer, a first blue light emitting stack comprising a first blue light emitting layer, and a second charge generation layer between the first electrode and the hole transport layer of the green light emitting stack and a third charge generation layer and a second blue light emitting stack comprising a second blue light emitting layer between the electron transport layer of the green light emitting stack and the second electrode.

In a light emitting display device according to one embodiment of the present disclosure, the green light emitting layer may be thicker than the red light emitting layer, the first blue light emitting layer, and the second blue light emitting layer.

In a light emitting display device according to one embodiment of the present disclosure, a content of the green dopant in the green light emitting layer may be higher than a content of a dopant in each of the red light emitting layer, the first blue light emitting layer, and the second blue light emitting layer.

In a light emitting display device according to one embodiment of the present disclosure, each of the first to third charge generation layers may comprise an n-type charge generation layer and a p-type charge generation layer. The hole transport layer of the green light emitting stack may contact the p-type charge generation layer of the second charge generation layer. The electron transport layer of the green light emitting stack may contact the n-type charge generation layer of the third charge generation layer.

In a light emitting display device according to one embodiment of the present disclosure, the second blue light emitting layer may be thicker than the first blue light emitting layer.

In a light emitting display device according to one embodiment of the present disclosure, two or more green light emitting stacks including the green light emitting stack may be laminated with a charge generation layer disposed therebetween.

A light emitting display device according to one embodiment of the present disclosure may comprise a substrate including a plurality of subpixels, a pixel circuit at each of the plurality of subpixels, the pixel circuit comprising at least one transistor and the light emitting device connected to the pixel circuit at at least one of the plurality of subpixels.

The light emitting device of the present disclosure and the light emitting display device including the same have the following effects.

The light emitting device and the light emitting display device including the same according to the embodiment of the present disclosure have a green dopant GD having a HOMO energy level lower than that of a hole transport host GHH in the green light emitting layer, so that, when holes are injected from the hole transport layer into the green light emitting layer, multiple passes of the green dopant, the hole transport host, and the electron transport host may be formed for hole movement.

Since holes or electrons are not trapped in the green dopant and contribute to exciton formation in each host and dopant, it is possible to prevent a problem of image quality deterioration caused by residual carriers charged in the green light emitting layer.

The light emitting device and the light emitting display device including the same contain a green dopant having a low HOMO energy level and an electron transport host having a small difference in HOMO energy level with the green dopant in the green light emitting layer, so that the onset voltage is higher than a predetermined level, the green layer has C-V characteristics that facilitate carrier charging and discharging, and the image quality deterioration that occurs when the green light emitting layer is switched on and off can be prevented.

The flashing phenomenon in which green emission spikes when switching from an off state to a low-grayscale state due to residual carriers in the green light emitting layer can be prevented or reduced.

The light emitting device and the light emitting display device including the same according to the embodiments of the present disclosure are capable of improving the efficiency of the light emitting layer and reducing the image quality deterioration, thus being continuously applicable and achieving ESG (environmental/social/governance) goals.

It will be apparent to those skilled in the art that various modifications and variations may be made in the present disclosure without departing from the spirit or scope of the inventions. Thus, it is intended that the present disclosure covers the modifications and variations of this invention provided they come within the scope of the appended claims and their equivalents.

What is claimed is:

1. A light emitting device comprising:
a first electrode and a second electrode facing each other; and
a green light emitting stack comprising a hole transport layer, a green light emitting layer, and an electron transport layer disposed between the first electrode and the second electrode,
wherein the green light emitting layer comprises a hole transport host, an electron transport host, and a green dopant,
a highest occupied molecular orbital (HOMO) energy level of the green dopant is lower than a HOMO energy level of the hole transport host and is higher than a HOMO energy level of the electron transport host, and
a HOMO energy level of the electron transport host is higher than the HOMO energy level of the electron transport layer.

2. The light emitting device according to claim 1, wherein the HOMO energy level of the hole transport host is lower than a HOMO energy level of the hole transport layer.

3. The light emitting device according to claim 1, wherein the HOMO energy level of the green dopant has a difference of 0.15 eV or less from the HOMO energy level of the hole transport host.

4. The light emitting device according to claim 1, wherein the green dopant is a phosphorescent dopant and comprises an iridium and an electron-withdrawing group.

5. The light emitting device according to claim 1, wherein the electron transport host comprises a bipolar compound in which an electron transport moiety and a hole transport moiety are linked to a linker through a first connecting portion and a second connecting portion.

6. The light emitting device according to claim 1, wherein the HOMO energy level of the electron transport host is 0.25 eV to 0.55 eV lower than the HOMO energy level of the green dopant.

7. The light emitting device according to claim 1, wherein the electron transport host has a widest energy band gap among materials contained in the green light emitting layer,
a lowest unoccupied molecular orbital (LUMO) energy level of the electron transport host is closer to a LUMO energy level of the hole transport host than to a LUMO energy level of the electron transport layer, and
the HOMO energy level of the electron transport host is closer to the HOMO energy level of the electron transport layer than to the HOMO energy level of the green dopant.

8. The light emitting device according to claim 1, wherein the green dopant is contained in an amount of 5 wt % to 25 wt % in the green light emitting layer.

9. The light emitting device according to claim 1, further comprising:
a red light emitting stack comprising a red light emitting layer, a first charge generation layer, a first blue light emitting stack comprising a first blue light emitting layer, and a second charge generation layer between the first electrode and the hole transport layer of the green light emitting stack; and
a third charge generation layer and a second blue light emitting stack comprising a second blue light emitting layer between the electron transport layer of the green light emitting stack and the second electrode.

10. The light emitting device according to claim 9, wherein the green light emitting layer is thicker than the red light emitting layer, the first blue light emitting layer, and the second blue light emitting layer.

11. The light emitting device according to claim 9, wherein a content of the green dopant in the green light emitting layer is higher than a content of a dopant in each of the red light emitting layer, the first blue light emitting layer, and the second blue light emitting layer.

12. The light emitting device according to claim 9, wherein each of the first to third charge generation layers comprises an n-type charge generation layer and a p-type charge generation layer,
the hole transport layer of the green light emitting stack contacts the p-type charge generation layer of the second charge generation layer, and
the electron transport layer of the green light emitting stack contacts the n-type charge generation layer of the third charge generation layer.

13. The light emitting device according to claim 9, wherein the second blue light emitting layer is thicker than the first blue light emitting layer.

14. The light emitting device according to claim 1, wherein two or more green light emitting stacks including the green light emitting stack are laminated with a charge generation layer disposed therebetween.

15. A light emitting display device comprising:
a substrate including a plurality of subpixels;
a pixel circuit at each of the plurality of subpixels, the pixel circuit comprising at least one transistor; and
the light emitting device according to claim 1, the light emitting device connected to the pixel circuit at at least one of the plurality of subpixels.
